(19) United States
(12) Patent Application Publication
(10) Pub. No.: US 2026/0047441 A1
(43) Pub. Date: Feb. 12, 2026

(54) SUBSTRATE DEVICE AND SEMICONDUCTOR PACKAGE

(71) Applicant: SMARTER MICROELECTRONICS (GUANG ZHOU) CO., LTD., Guangzhou (CN)

(72) Inventors: Xiaoyu WANG, Guangzhou (CN); Senlin DIAO, Guangzhou (CN); Tingting LI, Guangzhou (CN); Xiaoyu PENG, Guangzhou (CN); Jiangtao LIU, Guangzhou (CN)

(73) Assignee: SMARTER MICROELECTRONICS (GUANG ZHOU) CO., LTD., Guangzhou (CN)

(21) Appl. No.: 19/020,036

(22) Filed: Jan. 14, 2025

(30) Foreign Application Priority Data
Aug. 7, 2024 (CN) 202411079443.4

(51) Int. Cl. H01L 23/66; H01L 23/538; H01L 25/065

(52) U.S. Cl. CPC H01L 23/66; H01L 23/5383; H01L 23/5386; H01L 25/0655; H01L 2223/6611

(57) ABSTRACT

The embodiments of the present disclosure provide a substrate device and a semiconductor package, the substrate device includes: first insulating layers and first functional layers stacked alternately, each of the first functional layers having a metal pattern, where the metal pattern includes an inductance coil, and the substrate device is adaptable for being positioned on a substrate.

### CROSS-REFERENCE TO RELATED APPLICATION

The present application claims priority to Chinese Patent Application No. 202411079443.4 filed on Aug. 7, 2024, the disclosure of which is hereby incorporated by reference in its entirety.

### BACKGROUND

As the integration of semiconductor devices continues to improve, Radio Frequency (RF) front-end chips are becoming more and more widely used. Therefore, RF front-end chips need to support more frequency bands, need to be smaller in size, and need to be compatible with solutions supporting multiple countries and regions.

Inductors have great influence on the size, integration and performance of RF front-end chips. Therefore, it is urgent to provide a semiconductor device that meets the requirements of RF front-end chips and includes inductors.

### SUMMARY

In view of this, embodiments of the present disclosure provide a substrate device and a semiconductor package.

The present disclosure relates to the field of semiconductor devices, and in particularly to a substrate device and a semiconductor package.

In order to achieve the above object, the technical solution of the present disclosure is realized as follows.

According to a first aspect, an embodiment of the present disclosure provides a substrate device, which includes: first insulating layers and first functional layers stacked alternately, each of the first functional layers having a metal pattern, where the metal pattern includes an inductance coil, and the substrate device is adaptable for being positioned on a substrate.

In some embodiments, the substrate includes a plurality of second functional layers, each including a wiring pattern, and a spacing between neighboring first functional layers on the substrate device is less than a spacing between neighboring second functional layers on the substrate along a stacking direction, and the stacking direction is a direction along which the first insulating layers and the first functional layers are stacked.

In some embodiments, the substrate device is formed by a substrate process.

In some embodiments, the metal pattern includes a plurality of inductance coils.

In some embodiments, at least two of the plurality of inductance coils have different areas.

In some embodiments, the metal pattern further includes a capacitance plate and/or a balun.

In some embodiments, a plurality of solder balls are positioned on a first surface of the substrate device along a stacking direction, and the stacking direction is a direction along which the first insulating layers and the first functional layers are stacked.

According to a second aspect, an embodiment of the present disclosure provides a semiconductor package including the substrate device of any one of the above embodiments, and a substrate. The substrate device is positioned on the substrate.

In some embodiments, a plurality of the substrate devices are included.

In some embodiments, the substrate includes second insulating layers and second functional layers stacked alternately, and at least one of the following applies: a thickness of the substrate device is greater than a thickness of the substrate, or a number of the first functional layers of the substrate device is greater than a number of the second functional layers of the substrate.

In some embodiments, at least one of the following applies: at least two of the plurality of substrate devices have different thicknesses; or at least two of the plurality of substrate devices have different numbers of layers of the first functional layers.

In some embodiments, the substrate includes second insulating layers and second functional layers stacked alternately, and at least one of the following applies: a thickness of the first insulating layer is less than a thickness of the second insulating layer, or a thickness of the first functional layer is less than a thickness of the second functional layer.

In some embodiments, the substrate device further includes a first connection hole for connecting the inductance coils on neighboring first functional layers, and the substrate includes second insulating layers and second functional layers stacked alternately, and a second connection hole for connecting wiring patterns on neighboring second functional layers, where a size of the first connection hole is less than a size of the second connection hole.

In some embodiments, a semiconductor chip is further included, and at least one of the following applies: the semiconductor chip and/or the substrate device are positioned side by side on the substrate; or the semiconductor chip and/or the substrate device are stacked on the substrate.

In some embodiments, a first cavity is positioned between the semiconductor chip and the substrate, and a second cavity is positioned between the substrate device and the substrate.

The embodiments of the present disclosure provide a substrate device and a semiconductor package, the substrate device includes: first insulating layers and first functional layers stacked alternately, each of the first functional layers having a metal pattern, where the metal pattern includes an inductance coil, and the substrate device is adaptable for being positioned on a substrate. The substrate device in the embodiments of the present disclosure includes first functional layers, each having a metal pattern, where the metal pattern includes an inductance coil. A substrate device with a large inductance value is provided by alternately stacking the first functional layers having the metal patterns and the first insulating layers, so that it is possible to avoid embedding the inductances into the substrate to affect the thickness or area of the substrate.

### BRIEF DESCRIPTION OF THE DRAWINGS

FIG. 1 is a first schematic structural diagram of a substrate device according to an embodiment of the present disclosure.

FIG. 2 is a second schematic structural diagram of a substrate device according to an embodiment of the present disclosure.

FIG. 3 is a schematic diagram of a bottom surface of a substrate device according to an embodiment of the present disclosure.

FIG. 4 is a third schematic structural diagram of a substrate device according to an embodiment of the present disclosure.

FIG. 5 is a schematic diagram of a top view of the substrate device of FIG. 4 according to an embodiment of the present disclosure.

FIG. 6 is a fourth schematic structural diagram of a substrate device according to an embodiment of the present disclosure.

FIG. 7 is a schematic structural diagram of a substrate according to an embodiment of the present disclosure.

FIG. 8 is a schematic structural diagram of a semiconductor package according to an embodiment of the present disclosure.

### DETAILED DESCRIPTION

The technical solutions of the embodiments of the present disclosure will be clearly and completely described below in conjunction with the drawings in the embodiments of the present disclosure. It is apparent that the described embodiments are not all embodiments but part of embodiments of the present disclosure. All other embodiments obtained by those of ordinary skill in the art based on the embodiments in the present disclosure without creative work shall fall within the scope of protection of the present disclosure.

In the following description, numerous specific details are given to provide a more thorough understanding of the present disclosure. However, it will be apparent to those skilled in the art that the present disclosure may be implemented without one or more of these details. In other examples, in order to avoid confusion with the present disclosure, some technical features known in the art are not described. That is, all the features of the actual embodiments are not described here, and the known functions and structures are not described in detail.

In the drawings, the dimensions of layers, areas, and elements and their relative dimensions may be exaggerated for clarity. Throughout, the same reference numerals represent the same elements.

It is to be understood that description that an element or layer is “above/on”, “neighboring to”, “connected to/with”, or “coupled to” another element or layer may refer to that the element or layer is directly above, neighboring to, connected to or coupled to the other element or layer; or there may be an intermediate element or layer. On the contrary, description that an element is “directly on”, “directly neighboring to”, “directly connected to” or “directly coupled to” another element or layer refers to that there is no intermediate element or layer. It is to be understood that, although various elements, components, areas, layers, and/or parts may be described with terms first, second, third, etc., these elements, components, areas, layers, and/or parts should not be limited to these terms. These terms are used only to distinguish one element, component, area, layer or part from another element, component, area, layer or part. Therefore, a first element, component, area, layer, or part discussed below may be represented as a second element, component, area, layer, or part without departing from the teaching of the present disclosure. However, when the second element, component, area, layer, or part is discussed, it does not mean that the first element, component, area, layer, or part must exist in the present disclosure.

Spatially relational terms such as “below”, “under”, “lower”, “beneath”, “above”, and “upper” may be used herein for convenience of description to describe a relationship between one element or feature and another element or feature illustrated in the figures. It should be understood that in addition to the orientation shown in the figures, the spatially relational terms are intended to further include different orientations of devices in use and operation. For example, if the devices in the figures are turned over, elements or features described as being “under” or “beneath” or “below” other elements or features will be oriented to be “on” the other elements or features. Therefore, the exemplary terms “under” and “below” may include both upper and lower orientations. The device may be otherwise oriented (rotated by 90 degrees or in other orientations) and the spatial descriptors used herein may be interpreted accordingly.

The terms used herein are intended only to describe specific embodiments and are not a limitation of the disclosure. As used herein, singular forms “a/an”, “one”, and “the” may also be intended to include the plural forms, unless otherwise specified types in the context. It is also to be understood that, when terms “composed of” and/or “including” are used in this specification, the presence of the features, integers, steps, operations, elements, and/or components may be determined, but the presence or addition of one or more other features, integers, steps, operations, elements, components, and/or groups is also possible. As used herein, terms “and/or” includes any and all combinations of the related listed items.

For a thorough understanding of the present disclosure, detailed operations and detailed structures will be set forth in the following description in order to explain the technical solutions of the present disclosure. The preferred embodiments of the present disclosure are described in detail below. However, the present disclosure may also have other implementations in addition to these detailed descriptions.

It should be noted that, for convenience of description, various directions that may be used in the following description are defined first. The direction along which the first insulating layers and the first functional layers are stacked of the substrate device is defined as a vertical direction (i.e., the Z direction in the drawings). A first direction (i.e., the X direction in the drawings) and a second direction (i.e., the Y direction in the drawings) that intersect are defined in a plane perpendicular to the Z direction. The X direction, the Y direction, and the Z direction may be perpendicular to each other in pairs.

In some implementations, an RF front-end chip includes a substrate and an Integrated Circuit (IC) chip and an inductor positioned on the substrate, where the inductor is usually embedded in the substrate. However, embedding inductors in the substrate will increase the thickness or area of the substrate, which is a great problem for reducing the size of the chip and promoting the large-scale application of the chip.

Therefore, it is urgent to provide a semiconductor device with large inductance value, low cost and favorable to improving the integration degree of the RF front-end chips.

In view of this, an embodiment of the present disclosure provides a substrate device, which includes: first insulating layers and first functional layers stacked alternately, each of the first functional layers having a metal pattern, where the metal pattern includes an inductance coil, and the substrate device is adaptable for being positioned on a substrate.

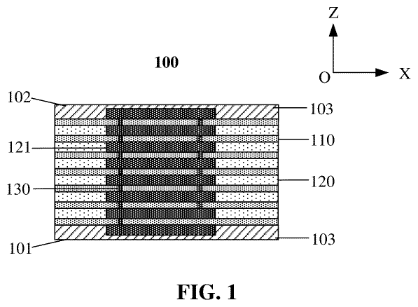

FIG. 1 is a schematic structural diagram of a substrate device according to an embodiment of the present disclosure. As shown in FIG. 1, the substrate device 100 includes first insulating layers 110 and first functional layers 120 stacked alternately, each of the first functional layers 120 has a metal pattern including an inductance coil 121, and the substrate device 100 is adaptable for being positioned on a substrate.

In some embodiments, it is possible to avoid embedding a inductor in the substrate by arranging the inductor in the substrate device, thereby reducing the substrate area. In addition, compared with embedding the inductor into the substrate, the substrate device can be more flexibly positioned on the substrate surface and has more design space. Furthermore, compared with embedding the inductor into the substrate, the substrate device can control the thickness of each first insulating layer and each first functional layer within a small range, so that the inductance coil is more compact. In addition, the substrate device provided by the embodiments of the present disclosure has the advantages of lower production cost and better performance compared to other devices having inductors.

It should be noted that, inductors in the substrate may all be replaced by inductors in the substrate device, that is, no inductors are positioned in the substrate, or some inductors in the substrate may be replaced by inductors in the substrate device, and some inductors in the substrate may be retained.

In some embodiments, the material of the first insulating layer 110 may include a prepreg (PPG) material including an insulating resin, an inorganic filler, and a glass fiber. The first functional layer 120 includes a metal pattern and a dielectric material, the dielectric material may include a prepreg material having the same or different etch selectivity than the first insulating layer. The first insulating layer may be made of other insulating materials, and the dielectric material may be made of other materials, and the materials of the first insulating layer and the dielectric material may be the same or different, and the present disclosure does not limit the specific materials of the dielectric material and the first insulating layer.

In some embodiments, the substrate device 100 is formed by a substrate process. Note that when there are a plurality of substrate devices, the parameters of the plurality of substrate devices may be the same or different. Where the parameters of the substrate device may include a coil width, a distance between neighboring coils in a coil stacking direction, a coil winding area, and the like.

In some embodiments, the substrate device 100 is formed by a substrate process. First, a base is positioned, and an adhesive layer is formed on the base. The base may be a glass base, a ceramic base, or the like. The adhesive layer may be removed together with the base from the substrate device to be formed in a subsequent step. Where the adhesive layer is any suitable adhesive, epoxy resin, die attach film (DAF), or the like, and the adhesive layer is applied on the surface of the base. In some embodiments, the adhesive layer is an epoxy-based heat release material that loses its adhesive properties when exposed to heat, such as a light-to-heat-conversion (LTHC) release coating. In other embodiments, the adhesive layer may be an ultra-violet (UV) adhesive that loses its adhesive properties when exposed to UV light. The substrate device 100 is then formed on the base by a substrate process.

In some embodiments, the first insulating layer 110 may be formed by pressing the prepreg material onto the adhesive layer. The first functional layer 120 includes a metal pattern and a dielectric material, where the dielectric material includes a prepreg material having a different etch selectivity than the first insulating layer. The first functional layer 120 having the metal pattern can be formed by sequentially forming the dielectric material and a patterned first mask layer on the first insulating layer 110, etching the dielectric material with the patterned first mask layer, using the first insulating layer 110 as a stop layer to form a notch for forming the metal pattern, and depositing a conductive material in the notch. Then, the first insulating layer 110 and the first functional layer 120 are alternately formed on the first functional layer 120 to constitute the substrate device 100.

In some embodiments, the first functional layer having the metal pattern can be formed by sequentially forming the dielectric material (including a prepreg material having a different etch selectivity than the first insulating layer 110) and a patterned second mask layer on the adhesive layer, etching the dielectric material with the patterned second mask layer, using the adhesive layer as a stop layer to form a notch for forming the metal pattern, and depositing a conductive material in the notch. Then, the first functional layer 120 and the first insulating layer 110 are alternately formed on the first functional layer 120 to constitute the substrate device 100.

It should be noted that the present disclosure does not limit whether the bottom surface or the top surface of the substrate device is the first functional layer or the first insulating layer.

In some embodiments, a metal layer may be formed on the surface of the first insulating layer 110 (or the adhesive layer) by a plating process, a patterned third mask layer may be formed on the metal layer, the metal layer may be etched by using the patterned third mask layer to form a metal pattern, and then the prepreg material may be pressed onto the metal pattern, to form the dielectric material of the first functional layer 120 (including the same prepreg material as the first insulating layer 110) and the next first insulating layer 110.

In some embodiments, the substrate device formed by the substrate process can reduce the production cost and make the substrate device have better performance compared to the devices with inductors formed by other IC processes.

Note that the specific number of the first insulating layers 110 and the first functional layers 120 in the present disclosure is not limited to the number shown in the figure, and the number of the first insulating layers 110 and the first functional layers 120 may be set according to the requirement of the inductance value.

In some embodiments, the substrate device 100 further includes a first connection hole 130 for connecting the inductance coils 121 on neighboring first functional layers 120.

In some embodiments, the first connection hole 130 is positioned in the first insulating layer 110, and the first connection hole 130 is used to connect the inductance coils 121 positioned in different first functional layers 120 to form an inductor. A via may be formed in the first insulating layer 110 by performing chemical etching with a mask, and the inner wall of the via may be plated with copper to connect the inductance coils 121 of the upper and lower layers. After copper plating, the via may be filled with the prepreg material to form the first connection hole 130. Filling the via with the prepreg material after copper plating may not only eliminate air, prevent the via from being expanded and broken when heated due to a large gas expansion coefficient, but also make the surface of the first insulating layer 110 smooth. It is also possible to form a first connection hole 130 connecting the inductance coils 121 of the upper and lower layers by performing chemical etching with a mask to form a via in the first insulating layer 110, and depositing the conductive material in the via. In addition, the first connection holes positioned at the top and bottom of the substrate device (the first connection holes positioned at the top and bottom of the substrate device are not shown in the figure) can also be used to electrically connect to a Pin or a solder ball to achieve electrical connections between the inductor and other devices.

The substrate device formed by the substrate process can effectively reduce the size of the first connection hole positioned in the first insulating layer and the thickness of the inductance coil positioned in the first functional layer compared with the inductance positioned in the substrate, so that the inductance coil of the inductor in the substrate device can be formed into a more compact structure.

In some embodiments, along the Z direction, the first surface of the substrate device is positioned with a plurality of solder balls. The Z direction is a stacking direction of the first insulating layer and the first functional layer.

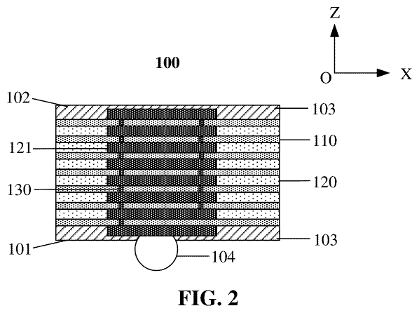

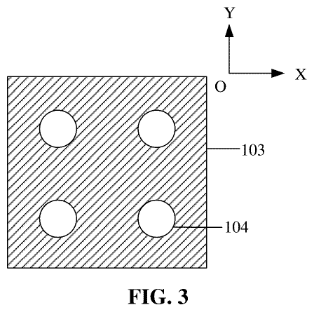

FIG. 2 is a second schematic structural diagram of a substrate device according to an embodiment of the present disclosure. FIG. 3 is a schematic diagram of a bottom surface of a substrate device according to an embodiment of the present disclosure, where FIG. 2 can be regarded as a partial cross-sectional view of FIG. 3. As shown in FIGS. 2 and 3, along the Z direction, the substrate device 100 includes a first surface 101 and a second surface 102 that are opposite to each other. The first surface 101 is the bottom surface of the substrate device, and the first surface 101 is positioned with four solder balls 104 that can electrically connect the substrate device 100 to the substrate, where the material of the solder ball 104 may include tin (Sn), indium (In), bismuth (Bi), antimony (Sb), Cu, silver (Ag), zinc (Zn), lead (Pb), and/or alloys thereof.

Note that the number of solder balls illustrated in FIGS. 2 and 3 is merely an exemplary description, and does not limit the number of solder balls. The number of solder balls may be another number, for example, one, two, three, or the like, and the present disclosure does not limit the number of solder balls 104.

In other embodiments, the substrate device may be positioned on the substrate by other means, such as Surface Mounted Technology (SMT) or through lead wires, and the present disclosure is not limited thereto.

As shown in FIGS. 1, 2, and 3, the first surface 101 and the second surface 102 of the substrate device 100 are coated with a solder mask layer 103 for preventing solder from flowing.

In some embodiments, the metal pattern includes a plurality of inductance coils 121, that is, a plurality of inductors are embedded in one substrate device. The metal pattern in at least one of the first functional layers 120 may include the inductance coils 121 of a plurality of inductors, and the spacing between the plurality of inductors on the XOY plane can be reduced with respect to the plurality of inductors respectively positioned on the substrate.

By mounting the substrate device integrated with the plurality of inductors on the substrate, the cost of mounting the plurality of inductors on the substrate is reduced, the surface area of the substrate wasted by the spacing between the inductors is reduced, the size of the RF front-end chip is reduced, the large-scale application of the RF front-end chip is promoted, and the performance comparable to the conventional RF front-end chip can be achieved.

In some embodiments, the substrate device 100 includes a plurality of first functional layers 120, where the number of inductance coils in each first functional layer may be the same or different, and the present disclosure does not limit the number of inductance coils in each first functional layer.

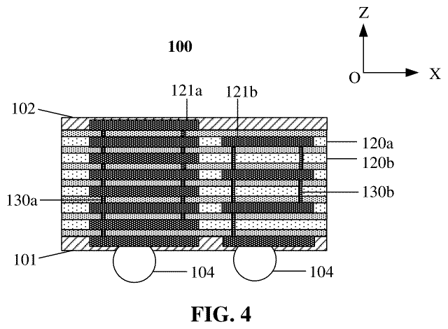

FIG. 4 is a third schematic structural diagram of a substrate device according to an embodiment of the present disclosure. As shown in FIG. 4, the inductance coils 121a and 121b of two inductors are included in the first functional layer 120a, the inductance coil 121a of one inductor is included in the first functional layer 120b, the inductance coils 121a are connected by the first connection hole 130a, and the inductance coils 121b are connected by the first connection hole 130b, so that inductors having different inductance values are included in the substrate device 100. Note that the diameter of the region through which the first connection hole 130b penetrates the first functional layer may be greater than the diameter of the region through which the first connection hole 130b penetrates the insulating layer. The number of the first insulating layers and the first functional layers through which the first connection hole penetrates may be set according to needs, and the present disclosure is not limited thereto.

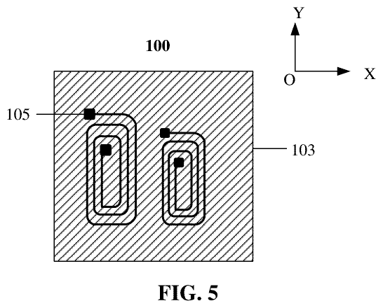

FIG. 5 is a schematic diagram of a top view of the substrate device of FIG. 4 according to an embodiment of the present disclosure. As shown in FIG. 5, the substrate device 100 includes two inductors, and the second surface 102 of the substrate device 100 may be positioned with a Pin 105 , and Pin 105 is a region without a solder mask layer on the second surface 102 of the substrate device, to expose a metal material under the solder mask layer. Pin 105 can be positioned with metal pins, which are used to realize the electrical connections between the inductor and other devices. It should be noted that a plurality of Pins may be positioned on the second surface of the substrate device 100 to lead out different inductors from different positions of the substrate device to obtain inductors with different inductance values, and the present disclosure does not limit the number of Pins. In addition, Pin can also indicate a position where the top surface of the substrate device is positioned.

In other embodiments, a plurality of inductors are included in the substrate device, the inductance value of at least one of the plurality of inductors is different or the same as the inductance values of the other inductors. In other words, the plurality of inductors may include a first inductor having a first inductance value and a second inductor having a second inductance value.

In some embodiments, at least two of the plurality of inductance coils have different areas.

In some embodiments, the areas of the inductance coils of two neighboring inductors may be the same or different, which is not limited in the present disclosure.

As shown in FIGS. 4 and 5, the substrate device 100 includes two inductors, and the number of inductance coils, the distance between the coils in the Z direction, the coil width, and the coil winding area of the two inductors are different. Note that when the substrate device includes a plurality of inductors, parameters such as the number of inductance coils, the distance between neighboring coils in the Z direction, the coil width, and the coil winding area of the plurality of inductors may be the same or different, and the present disclosure is not limited thereto.

In some embodiments, the metal pattern further includes a capacitance plate and/or a balun.

In some embodiments, the metal patterns in at least two of the first functional layers further includes capacitance plates, where the two capacitance plates opposite in the XOY plane may constitute a capacitor, so that the inductor and the capacitor may be integrated in the substrate device. In some embodiments, it is also possible to utilize the metal layer of the first functional layer as the capacitance plate of the capacitor, that is, the first functional layer does not include the dielectric material, but only includes the metal material used as the capacitance plate.

In some embodiments, the metal pattern in at least one of the first functional layers further includes a balun, so that the inductor and the balun device can be integrated in the substrate device.

In some embodiments, the metal patterns in at least two of the first functional layers further include capacitance plates, and the metal pattern in at least one of the first functional layers further include a balun, so that the inductor, the capacitor, and the balun device can be integrated in the substrate device.

In some embodiments, only the inductor is embedded in the substrate device, i.e., the metal pattern includes only the inductance coil.

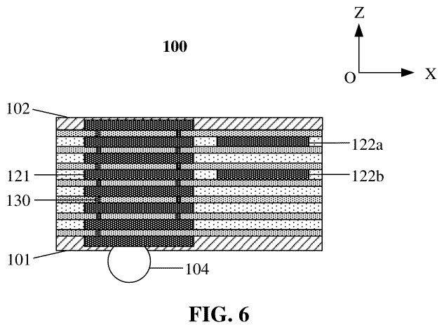

FIG. 6 is a fourth schematic structural diagram of a substrate device according to an embodiment of the present disclosure. As shown in FIG. 6, the metal patterns in two of the first functional layers 120 further include a capacitance plate 122a and a capacitance plate 122b, and the capacitance plate 122a and the capacitance plate 122b may constitute a capacitor, and the projections of the capacitance plate 122a and the capacitance plate 122b on the XOY plane overlap.

It should be noted that the projected areas of the two capacitance plates in the capacitor on the XOY plane may be the same or different. The capacitance plate may be multi-layered, and the present disclosure does not limit the area and the number of layers of the capacitance plate.

In some embodiments, in the case that the substrate device 100 includes a capacitor and/or a balun, the second surface of the substrate device 100 may be positioned with a plurality of Pins to lead the capacitor and/or the balun out from different positions on the second surface of the substrate device. Where the inductor, the capacitor, and the balun use different Pins.

In some embodiments, in the case that the substrate device 100 includes a capacitor, and there is an overlap between the projections of the capacitor and the inductor on the XOY plane, the substrate device 100 may further include a third connection hole, and the third connection hole may be used to achieve electrical connection between the inductor and the capacitor.

In some embodiments, the substrate device may further include other connection holes that lead the capacitor and/or the balun out to the first surface and/or the second surface of the substrate device.

The metal patterns in a part of the first functional layers may include only capacitance plates and/or baluns.

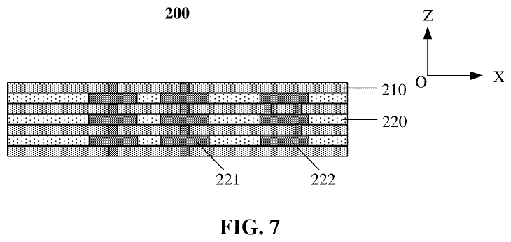

FIG. 7 is a schematic structural diagram of a substrate according to an embodiment of the present disclosure. As shown in FIG. 7, the substrate 200 is used for arranging electronic devices to enable interconnection between the electronic devices.

In some embodiments, the substrate 200 includes a plurality of second functional layers, and each of the second functional layers includes a wiring pattern 221. Referring to FIGS. 1 and 7, the spacing between the neighboring first functional layers 120 on the substrate device 100 is less than the spacing between the neighboring second functional layers 220 on the substrate 200 along the Z direction, and the Z direction is a stacking direction of the first insulating layers 110 and the first functional layers 120.

In some embodiments, the number of the first functional layers 120 in the substrate device 100 is greater than the number of the second functional layers 220 in the substrate 200.

In some embodiments, the spacing between neighboring first functional layers 120 on the substrate device 100 is less than the spacing between neighboring second functional layers 220 on the substrate 200, and the number of the first functional layers 120 in the substrate device 100 is greater than the number of the second functional layers 220 in the substrate 200.

In some embodiments, the substrate 200 further includes the inductance coil 222 positioned on the second functional layer, and since the spacing between the neighboring first functional layers 120 on the substrate device 100 is less than the spacing between the neighboring second functional layers 220 on the substrate 200, the spacing between the neighboring inductance coils 121 on the substrate device 100 is less than the spacing between the neighboring inductance coils 222 on the substrate 200.

It should be noted that, in some embodiments, the second functional layer may also omit the inductance coil 222, and the inductor in the substrate may be replaced by the inductor in the substrate device to reduce the area of the substrate.

In some embodiments, the substrate 200 includes second insulating layers 210 and second functional layers 220 stacked alternately. Along the Z direction, the spacing between the neighboring first functional layers 120 on the substrate device 100 is less than the spacing between the neighboring second functional layers 220 on the substrate 200, that is, the thickness of the first insulating layer 110 is less than the thickness of the second insulating layer 210.

Note that, in a case that more than one first insulating layer is included between neighboring inductance coils on the substrate device along the Z direction (for example, a plurality of first insulating layers and a first functional layer are included between neighboring inductance coils on the substrate device), the spacing between neighboring inductance coils on the substrate device along the Z direction may be equal to or even greater than the spacing between neighboring inductance coils on the substrate.

The substrate and the substrate device may select the same substrate parameters or different substrate parameters.

In some embodiments, in order to meet the requirement for the inductance value of the inductor, since the number of the second functional layers in the substrate is limited, the substrate usually increases the area of the substrate to provide an inductor with a larger winding area in the substrate, so that the requirement for the inductance value of the inductor can be met, but will lead to the problem that the overall area of the RF front-end chip becomes larger. However, in the substrate device provided by the present disclosure, the number of the first insulating layers 110 and the first functional layers 120 can be flexibly set without being limited by the number of layers of the substrate, so that inductors with various inductance values meet the requirement of the RF front-end chips can be provided.

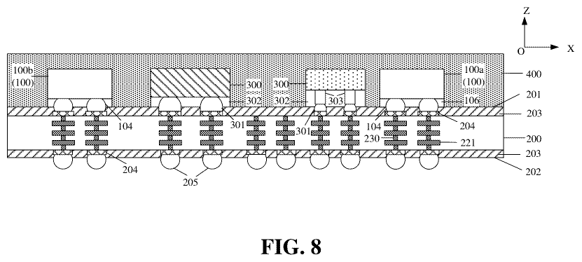

FIG. 8 is a schematic structural diagram of a semiconductor package according to an embodiment of the present disclosure. As shown in FIG. 8, the semiconductor package includes the substrate device 100 of any one of the above-described embodiments, and a substrate 200. The substrate device 100 is positioned on the substrate 200.

In some embodiments, the substrate 200 includes a first surface 201 and a second surface 202 opposite to each other. The first surface 201 and the second surface 202 include pads 204 exposed via a solder mask layer 203. The semiconductor package further includes solder balls 104 and solder balls 205 attached to the pads 204, the solder balls 104 may mount the substrate device 100a and the substrate device 100b on the substrate 200, and the solder balls 205 may enable electrical connections between the substrate 200 and other devices. The solder balls 104 and the solder balls 205 may be replaced by other connection structures, such as connection wires and the like.

It should be noted that the pad 204 is exposed via the solder mask layer 203 on the surface of the substrate 200, the material of the pad 204 may include copper, nickel, stainless steel, or beryllium copper, and the materials of the solder ball 104 and the solder ball 205 may include tin (Sn), indium (In), bismuth (Bi), antimony (Sb), Cu, silver (Ag), zinc (Zn), lead (Pb), and/or alloys thereof. The materials of the solder ball 104 and the solder ball 205 may be the same or different.

In some embodiments, the semiconductor package includes a plurality of substrate devices 100.

As shown in FIG. 8, the substrate device 100a and the substrate device 100b are positioned on the first surface 201 of the substrate 200 according to the area of the substrate and the layout of other devices on the substrate.

In some embodiments, at least two of the plurality of substrate devices have different thicknesses, and/or at least two of the plurality of substrate devices have different numbers of layers of the first functional layers.

In some embodiments, the thickness of the substrate device 100a is different from the thickness of the substrate device 100b, and the number of stacked layers of the substrate device 100a is different from the number of stacked layers of the substrate device 100b when the process parameters of the two substrate devices are the same. In this way, substrate devices having different inductance values can be positioned on the substrate as needed. In some embodiments, the plurality of substrate devices have different numbers of layers to form inductors having different numbers of inductance coils in the plurality of substrate devices, respectively, to form substrate devices with inductors having different inductance values.

In some embodiments, the thickness of the substrate device 100a is different from the thickness of the substrate device 100b, and when the process parameters of the two substrate devices are different, the number of the first functional layers of the substrate device 100a and the number of the first functional layers of the substrate device 100b may be the same or different.

In some embodiments, the number of the first functional layers of the substrate device 100a is different from the number of the first functional layers of the substrate device 100b, and when the process parameters of the two substrate devices are different, the thickness of the substrate device 100a and the thickness of the substrate device 100b may be the same or different.

In some embodiments, the number of the first functional layers of the substrate device 100a is different from the number of the first functional layers of the substrate device 100b, and when the process parameters of the two substrate devices are the same, the thickness of the substrate device 100a and the thickness of the substrate device 100b may be the same.

The thicknesses of the first functional layer and/or the first insulating layer of different substrate devices may be different. In addition, the inductance coil areas of the inductors embedded in different substrate devices may be the same or different, and when the coil areas are different, the inductors in the substrate devices may have the same inductance value by different numbers of coil layers.

In some embodiments, the substrate 200 includes second insulating layers 210 and second functional layers 220 stacked alternately. The thickness of the substrate device 100 is greater than the thickness of the substrate 200, and/or the number of the first functional layers 120 of the substrate device 100 is greater than the number of the second functional layers 220 of the substrate 200.

The number of stacked layers of the substrate 200 is usually positioned according to the complexity of the circuit, and the number of stacked layers of the substrate 200 is limited. The substrate device 100 is positioned on the substrate 200 as a device structure, and the number of stacked layers of the substrate device 100 can be greater than that of the substrate 200, and the number of stacked layers of the substrate device 100 can be set more flexibly, thus forming a structure thicker than that of the substrate 200, so that the inductor in the substrate device 100 has a larger inductance value. In addition, the positions of the substrate devices may also be set as desired, and the spacing between the plurality of substrate devices having inductors may be increased to reduce coupling.

In some embodiments, the number of the first functional layers 120 of the substrate device 100 is greater than the number of the second functional layers 220 of the substrate 200. Since the thickness of the first insulating layer 110 in the substrate device 100 may be less than the thickness of the second insulating layer 210 in the substrate 200, and the thickness of the first functional layer 120 in the substrate device 100 may be less than the thickness of the second functional layer 220 in the substrate 200, the thickness of the substrate device 100 may be less than or equal to the thickness of the substrate 200.

In some embodiments, the area of the substrate device 100 is less than the area of the substrate 200 on the XOY plane, and the inductance value of the inductor in the substrate device may be increased by increasing the number of layers of the inductance coils or changing the process parameters of the substrate device, so that the area of the inductance coil may be in a smaller range such that the area of the substrate device is less than the area of the substrate.

In some embodiments, the substrate 200 includes second insulating layers 210 and second functional layers 220 stacked alternately. The thickness of the first insulating layer 110 is less than the thickness of the second insulating layer 210, and/or the thickness of the first functional layer 120 is less than the thickness of the second functional layer 220.

In other embodiments, the thickness of the first insulating layer may be equal to or greater than the thickness of the second insulating layer, and/or the thickness of the first functional layer may be equal to or greater than the thickness of the second functional layer.

In some embodiments, the substrate device 100 further includes a first connection hole for connecting inductance coils on neighboring first functional layers. The substrate 200 further includes a second connection hole 230 for connecting wiring patterns 221 on neighboring second functional layers. The size of the first connection hole is less than the size of the second connection hole 230.

In other embodiments, the second connection hole is further used to connect inductance coils on neighboring second functional layers.

In some embodiments, since the first connection hole and the second connection hole are vias with a large upper size and a small lower size formed by performing chemical etching with a mask, and the thickness of the first insulating layer is less than the thickness of the second insulating layer, the opening size for forming the first connection hole is less than that of the second connection hole.

In some embodiments, a semiconductor chip is further included. The semiconductor chip and/or the substrate device are positioned side by side on the substrate, and/or the semiconductor chip and/or the substrate device are stacked on the substrate.

In some embodiments, the semiconductor chip and/or the substrate device are positioned side by side on the substrate, that is, at least two devices positioned on the substrate are positioned side by side. For example, two semiconductor chips are positioned side by side on the substrate. For another example, two substrate devices are positioned side by side on the substrate. For yet another example, one semiconductor chip and one substrate device are positioned side by side on the substrate.

In some embodiments, the semiconductor chip and/or substrate device are stacked on the substrate, that is, at least two devices positioned on the substrate are stacked. For example, two semiconductor chips are stacked on the substrate. For another example, two substrate devices are stacked on the substrate. For yet another example, one semiconductor chip and one substrate device are stacked on the substrate.

In some embodiments, the semiconductor chip and/or the substrate device are positioned side by side on the substrate, and the semiconductor chip and/or the substrate device are stacked on the substrate, that is, the devices provided on the substrate may be positioned side by side or stacked.

Any two of the semiconductor chip, the substrate device and the substrate can be electrically connected by solder balls. For example, a semiconductor chip is positioned on a substrate device or a substrate by using solder balls, or a substrate device is positioned on a semiconductor chip or a substrate by using solder balls. In other embodiments, the connection may be performed by SMT, a connection wire, or the like.

In some embodiments, a first cavity 302 is positioned between the semiconductor chip 300 and the substrate 200, and a second cavity 106 is positioned between the substrate device 100 and the substrate 200.

In some embodiments, the semiconductor package further includes a molding layer 400 for encapsulating the substrate device 100 and the semiconductor chip 300, and the molding layer 400 does not cover at least one electrical connection region between the semiconductor chip 300 and the substrate 200, so that the first cavity 302 is formed between the semiconductor chip 300 and the substrate 200.

In some embodiments, the semiconductor chip is a chip having a cavity, for example, one or more of a bulk acoustic wave resonator chip, a surface acoustic wave resonator chip, and a bulk acoustic wave filter chip. When the chip having a cavity is packaged, the cavity needs to be retained to prevent the molding layer 400 from affecting the performance of the chip having a cavity. Therefore, in some embodiments, the first cavity 302 formed by using the solder ball 301 can retain the cavity structure in the chip. In other embodiments, the first cavity may also be formed by other connection structures, which is not limited in the present disclosure. The material of the solder ball 301 may include tin (Sn), indium (In), bismuth (Bi), antimony (Sb), Cu, silver (Ag), zinc (Zn), lead (Pb), and/or alloys thereof. The materials of the solder ball 301, the solder ball 104, and the solder ball 205 may be the same or different.

In some embodiments, a conductive pillar 303 positioned between the semiconductor chip 300 and the substrate 200 is further included. The conductive pillar 303 is used to control the height of the first cavity 302 along the stacking direction. The stacking direction is a stacking direction of the first insulating layer and the first functional layer.

In some embodiments, the semiconductor chip 300 and the substrate 200 are connected by a conductive pillar 303. Since the height of the conductive pillar 303 is controllable, it is beneficial to control the height of the first cavity 302, and the semiconductor chip can be further avoided from being contaminated.

In some embodiments, the molding layer 400 does not cover at least one electrical connection area between the substrate device 100 and the substrate 200, so that the second cavity 106 is formed between the substrate device 100 and the substrate 200.

The solder ball 104 between the substrate device and the substrate prevent the molding layer 400 from covering the region where the substrate device 100 and the substrate 200 are electrically connected, thereby forming the second cavity 106. Since the substrate device has the second cavity, the first surface thereof is not entirely mounted on the substrate, the soldering area thereof is small, and contamination of the semiconductor chip having the cavity can be avoided. The connection structure may be a solder ball, or may be other connection structures, for example, a connection wire, a conductive pillar, or the like.

It should be noted that unmarked parts in FIGS. 1 to 8 of the present disclosure may be shared with each other.

Note that the above description of the semiconductor package is similar to the above description of the embodiments of the substrate device, and has beneficial effects similar to those of the embodiments of the substrate device. For technical details not disclosed in the embodiments of the semiconductor package of the present disclosure, please refer to the description of the embodiments of the substrate device of the present disclosure.

The embodiments of the present disclosure provide a substrate device and a semiconductor package, the substrate device includes: first insulating layers and first functional layers stacked alternately, each of the first functional layers having a metal pattern, where the metal pattern includes an inductance coil, and the substrate device is adaptable for being positioned on a substrate. The substrate device in the embodiments of the present disclosure includes first functional layers, each having a metal pattern, where the metal pattern includes an inductance coil. A substrate device with a large inductance value is provided by alternately stacking the first functional layers having the metal patterns and the first insulating layers, so that it is possible to avoid embedding the inductances into the substrate to affect the thickness or area of the substrate.

It should be understood that “one embodiment” or “an embodiment” mentioned throughout the specification means that specific features, structures, or characteristics related to the embodiment is included in at least one embodiment of the disclosure. Therefore, the appearances of “in one embodiment” or “in an embodiment” in various places throughout the specification do not necessarily refer to the same embodiment. In addition, these specific features, structures, or characteristics can be combined in one or more embodiments in any suitable manner. It should be understood that, in the various embodiments of the disclosure, the size of the serial number of the above-mentioned processes does not mean the order of execution, and the execution order of each process should be determined by its function and internal logic, and should not constitute any limitation to the implementation process of the embodiments of the disclosure. The serial numbers of the foregoing embodiments of the disclosure are only for description, and do not represent the advantages and disadvantages of the embodiments.

The above is only preferred embodiments of the present disclosure, and does not limit the patent scope of the present disclosure accordingly. Any equivalent structural transformation made by the contents of the present specification and the drawings, or directly/indirectly application to other related technical fields under the inventive conception of the present disclosure is included in the patent protection scope of the present disclosure.

1. A substrate device, comprising:
first insulating layers and first functional layers stacked alternately, each of the first functional layers having a metal pattern, wherein the metal pattern comprises an inductance coil, and the substrate device is adaptable for being positioned on a substrate.

2. The substrate device of claim 1, wherein the substrate comprises a plurality of second functional layers, each second functional layer comprising a wiring pattern, and
a spacing between neighboring first functional layers on the substrate device is less than a spacing between neighboring second functional layers on the substrate along a stacking direction, and the stacking direction is a direction along which the first insulating layers and the first functional layers are stacked.

3. The substrate device of claim 1, wherein the substrate device is formed by a substrate process.

4. The substrate device of claim 1, wherein the metal pattern comprises a plurality of inductance coils.

5. The substrate device of claim 4, wherein at least two of the plurality of inductance coils have different areas.

6. The substrate device of claim 1, wherein the metal pattern further comprises a capacitance plate and/or a balun.

7. The substrate device of claim 1, wherein a plurality of solder balls are positioned on a first surface of the substrate device along a stacking direction, and the stacking direction is a direction along which the first insulating layers and the first functional layers are stacked.

8. A semiconductor package, comprising: the substrate device of claim 1, and the substrate,
wherein the substrate device is positioned on the substrate.

9. The semiconductor package of claim 8, comprising: a plurality of the substrate devices.

10. The semiconductor package of claim 8, wherein the substrate comprises second insulating layers and second functional layers stacked alternately, and
a thickness of the substrate device is greater than a thickness of the substrate, and/or a number of the first functional layers of the substrate device is greater than a number of the second functional layers of the substrate.

11. The semiconductor package of claim 9, wherein
at least two of the plurality of substrate devices have different thicknesses; and/or
at least two of the plurality of substrate devices have different numbers of layers of the first functional layers.

12. The semiconductor package of claim 8, wherein the substrate comprises second insulating layers and second functional layers stacked alternately, and
a thickness of the first insulating layer is less than a thickness of the second insulating layer, and/or a thickness of the first functional layer is less than a thickness of the second functional layer.

13. The semiconductor package of claim 8, wherein the substrate device further comprises a first connection hole for connecting the inductance coils on neighboring first functional layers, and
the substrate comprises second insulating layers and second functional layers stacked alternately, and a second connection hole for connecting wiring patterns on neighboring second functional layers, wherein a size of the first connection hole is less than a size of the second connection hole.

14. The semiconductor package of claim 8, further comprising: a semiconductor chip, and
the semiconductor chip and/or the substrate device are positioned side by side on the substrate; and/or
the semiconductor chip and/or the substrate device are stacked on the substrate.

15. The semiconductor package of claim 14, wherein a first cavity is positioned between the semiconductor chip and the substrate, and a second cavity is positioned between the substrate device and the substrate.
